(19) United States
(12) Patent Application Publication
(10) Pub. No.: US 2025/0102919 A1
(43) Pub. Date: Mar. 27, 2025

(54) DIFFERENTIAL EVACUATION DEVICE AND ELECTRONIC DEVICE MANUFACTURING METHOD

(71) Applicant: Gigaphoton Inc., Tochigi (JP)

(72) Inventor: Atsushi UEDA, Oyama-shi (JP)

(73) Assignee: Gigaphoton Inc., Tochigi (JP)

(21) Appl. No.: 18/807,607

(22) Filed: Aug. 16, 2024

(30) Foreign Application Priority Data
Sep. 27, 2023 (JP) 2023-166241

(51) Int. Cl. G03F 7/00; G03F 1/22

(52) U.S. Cl. CPC G03F 7/70033; G03F 1/22

(57) ABSTRACT

A differential evacuation device includes a connection pipe connecting a first chamber which outputs extreme ultraviolet light and a second chamber to which the extreme ultraviolet light is input, a first partition wall including a first opening and a first partition plate being arranged such that the extreme ultraviolet light passes through the first opening, a second partition wall including a second opening and a second partition plate being arranged such that the extreme ultraviolet light passes through the second opening, and a first exhaust port exhausting a gas in a first differential evacuation chamber between the first partition wall and the second partition wall. Here, the first partition wall is arranged such that the second opening is surrounded by a portion outside a first high pressure region where a pressure is highest in pressure distribution at the second partition plate on the first differential evacuation chamber side.

### CROSS-REFERENCE TO RELATED APPLICATIONS

The present application claims the benefit of Japanese Patent Application No. 2023-166241, filed on Sep. 27, 2023, the entire contents of which are hereby incorporated by reference.

### BACKGROUND

### 1. Technical Field

The present disclosure relates to a differential evacuation device and an electronic device manufacturing method.

### 2. Related Art

Recently, miniaturization of a transfer pattern in optical lithography of a semiconductor process has been rapidly proceeding along with miniaturization of the semiconductor process. In the next generation, microfabrication at 10 nm or less will be required. Therefore, it is expected to develop a semiconductor exposure apparatus that combines an apparatus for generating extreme ultraviolet (EUV) light having a wavelength of about 13 nm with a reduced projection reflection optical system.

As the EUV light generation apparatus, a laser produced plasma (LPP) type apparatus using plasma generated by irradiating a target substance with laser light has been developed.

### LIST OF DOCUMENTS

### Patent Documents

Patent Document 1: US Patent Application Publication No. 2009/314967
Patent Document 2: US Patent Application Publication No. 2004/046949

### SUMMARY

A differential evacuation device according to an aspect of the present disclosure includes a connection pipe which connects a first chamber which outputs extreme ultraviolet light and a second chamber to which the extreme ultraviolet light is input as having a pressure lower than the first chamber, a first partition wall including a first opening and a first partition plate surrounding the first opening and being arranged such that the extreme ultraviolet light passes through the first opening, a second partition wall including a second opening smaller than the first opening and a second partition plate surrounding the second opening and being arranged such that the extreme ultraviolet light having passed through the first opening passes through the second opening, and a first exhaust port configured to exhaust a gas in a first differential evacuation chamber between the first partition wall and the second partition wall. Here, the first partition wall is arranged such that the second opening is surrounded by a portion outside a first high pressure region where a pressure is highest in pressure distribution at the second partition plate on the first differential evacuation chamber side.

An electronic device manufacturing method according to an aspect of the present disclosure includes generating extreme ultraviolet light using an extreme ultraviolet light generation system, outputting the extreme ultraviolet light to an exposure apparatus including a second chamber, and exposing a photosensitive substrate to the extreme ultraviolet light in the exposure apparatus to manufacture an electronic device. Here, the extreme ultraviolet light generation system includes a first chamber and a differential evacuation device. The differential evacuation device includes a connection pipe which connects the first chamber which outputs the extreme ultraviolet light and the second chamber to which the extreme ultraviolet light is input as having a pressure lower than the first chamber, a first partition wall including first opening and a first partition plate surrounding the first opening and being arranged such that the extreme ultraviolet light passes through the first opening, a second partition wall including a second opening smaller than the first opening and a second partition plate surrounding the second opening and being arranged such that the extreme ultraviolet light having passed through the first opening passes through the second opening, and a first exhaust port configured to exhaust a gas in a first differential evacuation chamber between the first partition wall and the second partition wall. The first partition wall is arranged such that the second opening is surrounded by a portion outside a first high pressure region where a pressure is highest in pressure distribution at the second partition plate on the first differential evacuation chamber side.

An electronic device manufacturing method according to an aspect of the present disclosure includes inspecting a defect of a mask by irradiating the mask with extreme ultraviolet light generated by an extreme ultraviolet light generation system, selecting a mask using a result of the inspection, and exposing and transferring a pattern formed on the selected mask onto a photosensitive substrate. Here, the extreme ultraviolet light generation system includes a first chamber and a differential evacuation device. The differential evacuation device includes a connection pipe which connects the first chamber which outputs the extreme ultraviolet light and a second chamber to which the extreme ultraviolet light is input as having a pressure lower than the first chamber, a first partition wall including a first opening and a first partition plate surrounding the first opening and being arranged such that the extreme ultraviolet light passes through the first opening, a second partition wall including a second opening smaller than the first opening and a second partition plate surrounding the second opening and being arranged such that the extreme ultraviolet light having passed through the first opening passes through the second opening, and a first exhaust port configured to exhaust a gas in a first differential evacuation chamber between the first partition wall and the second partition wall. The first partition wall is arranged such that the second opening is surrounded by a portion outside a first high pressure region where a pressure is highest in pressure distribution at the second partition plate on the first differential evacuation chamber side.

### BRIEF DESCRIPTION OF THE DRAWINGS

Embodiments of the present disclosure will be described below merely as examples with reference to the accompanying drawings.

FIG. 1 shows the configuration of an LPP-type EUV light generation system according to a comparative example.

FIG. 2 shows the configuration of an EUV light generation apparatus shown in FIG. 1.

FIG. 3 shows the configuration of a differential evacuation device shown in FIG. 1.

FIG. 4 shows the configuration of the differential evacuation device according to a first embodiment.

FIG. 5 shows the dimensions of the respective parts of the differential evacuation device shown in FIG. 4.

FIG. 6 shows a simulation result of the pressure distribution at a second partition plate on a first differential evacuation chamber side in the comparative example.

FIG. 7 shows a simulation result of the pressure distribution at the second partition plate on the first differential evacuation chamber side in the first embodiment.

FIG. 8 shows the position of a first exhaust port in the differential evacuation device shown in FIG. 4.

FIG. 9 shows the configuration of the differential evacuation device according to a second embodiment.

FIG. 10 shows the dimensions of the respective parts of the differential evacuation device shown in FIG. 9.

FIG. 11 shows the position of the first exhaust port in the differential evacuation device shown in FIG. 9.

FIG. 12 shows the configuration of the differential evacuation device according to a modification of the second embodiment.

FIG. 13 shows the configuration of the differential evacuation device according to a third embodiment.

FIG. 14 is a perspective view of a first partition wall shown in FIG. 13.

FIG. 15 shows the configuration of the differential evacuation device according to a modification of the third embodiment.

FIG. 16 is a perspective view of the first partition wall shown in FIG. 15.

FIG. 17 shows the configuration of the differential evacuation device according to a fourth embodiment.

FIG. 18 schematically shows the configuration of an exposure apparatus connected to the EUV light generation system.

FIG. 19 schematically shows the configuration of an inspection apparatus connected to the EUV light generation system.

### DESCRIPTION OF EMBODIMENTS

### <Contents>

1. Comparative example
1.1 Configuration
1.2 Operation
2. Problem of comparative example
3. Differential evacuation device 90a in which partition wall 91a is obliquely arranged first
3.1 Configuration
3.2 Pressure distribution at second partition plate 922 on first differential evacuation chamber 910 side
3.3 Position of first exhaust port 61
3.4 Effect
4. Differential evacuation devices 90b, 90c in which first opening 911 is obliquely formed
4.1 Configuration
4.2 Position of first exhaust port 61
4.3 Modification
4.4 Effect
5. Differential evacuation devices 90d, 90e in which thickness of first partition plate 912 is partially different
5.1 Configuration
5.2 Modification
5.3 Effect
6. Differential evacuation device 90f including plurality of differential evacuation chambers 910, 920, 930
6.1 Configuration
6.2 Position of second and third exhaust ports 62, 63
6.3 Effect
7. Others
7.1 Examples of EUV light utilization apparatus 6
7.2 Supplement

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Comparative Example

### 1.1 Configuration

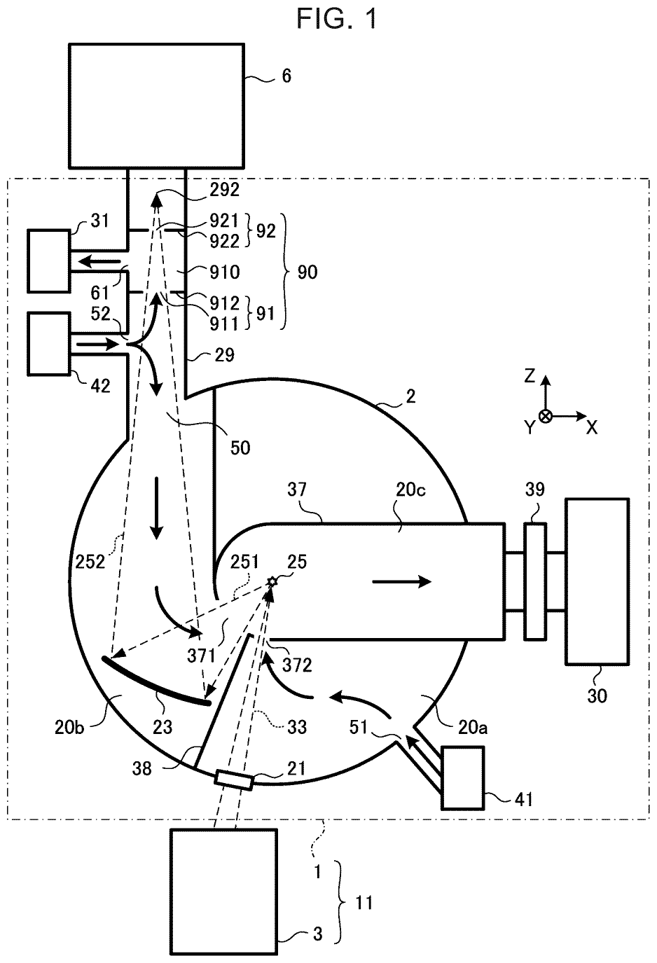

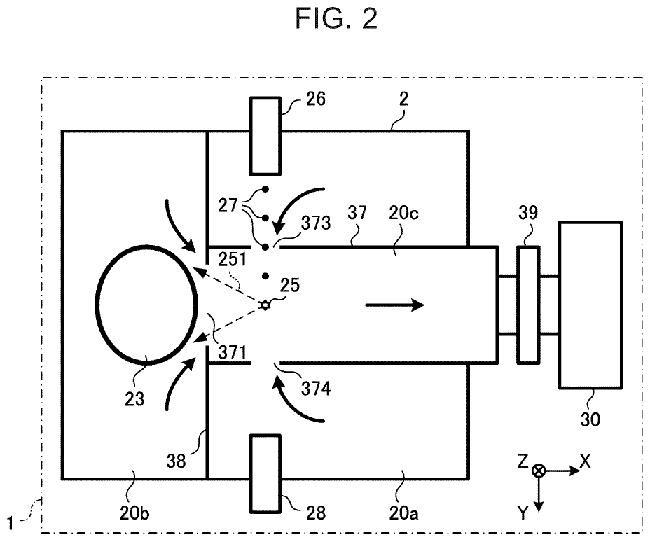

FIG. 1 shows the configuration of an LPP-type EUV light generation system 11 according to a comparative example, and FIG. 2 shows the configuration of an EUV light generation apparatus 1 shown in FIG. 1. In FIGS. 1 and 2, the X direction, the Y direction, and the Z direction perpendicular to each other are shown. FIG. 1 is a view of the EUV light generation system 11 viewed in the Y direction, and FIG. 2 is a view of the EUV light generation apparatus 1 viewed in the Z direction. The Y direction is an output direction of a target 27, and the Z direction is an output direction of EUV light.

An EUV light generation apparatus 1 is used together with a laser device 3. In the present disclosure, a system including the EUV light generation apparatus 1 and the laser device 3 is referred to as the EUV light generation system 11. The EUV light generation apparatus 1 includes a chamber 2, a first inner wall 37, and a second inner wall 38.

The chamber 2 is a sealable container and has a substantially cylindrical shape. The center axis of the cylindrical shape is parallel to the Y direction, and a target supply unit 26 and a target collection unit 28 are arranged at positions on the center axis. A plasma generation region 25 is located between the target supply unit 26 and the target collection unit 28. The chamber 2 corresponds to the first chamber in the present disclosure.

The first inner wall 37 has a cylindrical shape and penetrates the side surface of the chamber 2. The center axis of the cylindrical shape is parallel to the X direction.

A part of the first inner wall 37 is located inside the chamber 2 and is arranged to cover the plasma generation region 25. Another part of the first inner wall 37 is located outside the chamber 2 and is connected to an exhaust device 30. A gate valve 39 is arranged between the first inner wall 37 and the exhaust device 30. The second inner wall 38 separates the space inside the chamber 2 and outside the first inner wall 37 into a first space 20a and a second space 20b.

In the chamber 2, the first inner wall 37 has first to fourth through holes 371 to 374. The first through hole 371 is configured to provide communication between the second space 20b and a third space 20c, which is a space inside the first inner wall 37. The second to fourth through holes 372 to 374 are configured to provide communication between the first space 20a and the third space 20c.

The target supply unit 26 supplies the target 27 containing a target substance into the chamber 2. The material of the target substance may include tin, terbium, gadolinium, lithium, xenon, or a combination of any two or more thereof.

A window 21 is arranged in the wall of the chamber 2. Pulse laser light 33 output from the laser device 3 passes through the window 21. A gas supply source 41 for supplying a gas to the first space 20a through a first gas supply port 51 is connected to the chamber 2. The gas to be supplied is, for example, hydrogen gas.

An EUV light concentrating mirror 23 having a spheroidal reflection surface is arranged in the second space 20b. A multilayer reflective film in which molybdenum and silicon are alternately laminated is formed on the reflection surface. The EUV light concentrating mirror 23 has first and second focal points. The EUV light concentrating mirror 23 is arranged such that the first focal point is located in a plasma generation region 25 and the second focal point is located at an intermediate focal point 292.

The first through hole 371 is located on the optical path of radiation light 251 including EUV light generated at the plasma generation region 25 and directed toward the EUV light concentrating mirror 23. An opening 50 of the chamber 2 is located on the optical path of reflection light 252 directed toward the intermediate focal point 292 from the EUV light concentrating mirror 23. The EUV light concentrating mirror 23 is arranged such that the center axis of the optical path of the reflection light 252 is inclined with respect to the center axis of the optical path of the radiation light 251.

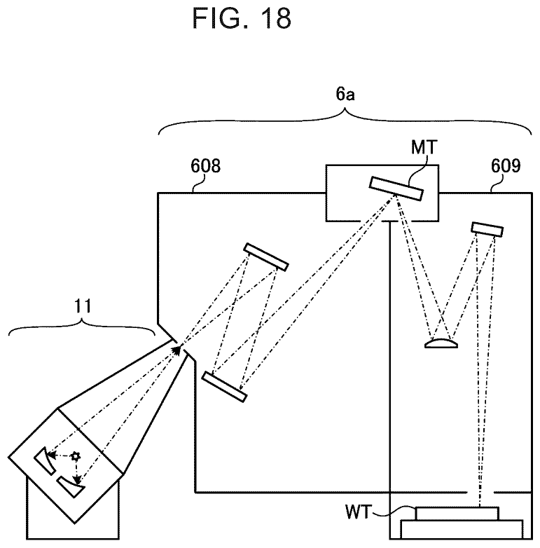

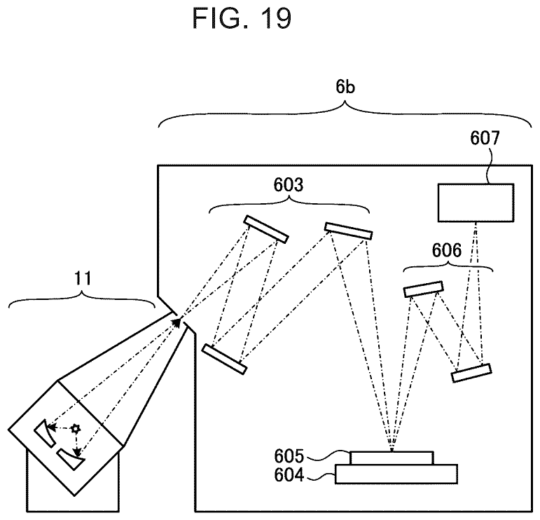

The EUV light generation apparatus 1 includes a connection pipe 29 connected to the opening 50 to connect the chamber 2 and a chamber of the EUV light utilization apparatus 6. The chamber of the EUV light utilization apparatus 6 corresponds to the second chamber in the present disclosure. The EUV light utilization apparatus 6 may be an exposure apparatus 6a shown in FIG. 18 or an inspection apparatus 6b shown in FIG. 19. A wall (not shown) in which an aperture is formed at the position of the intermediate focal point 292 may be provided in the connection pipe 29. A gas supply source 42 for supplying a gas to the second space 20b through a second gas supply port 52 and the opening 50 is connected to the connection pipe 29. The gas to be supplied is, for example, hydrogen gas.

A differential evacuation device 90 is arranged in the connection pipe 29 at a position between the intermediate focal point 292 and the second gas supply port 52. The differential evacuation device 90 includes a part of the connection pipe 29, first and second partition walls 91, 92 arranged in the connection pipe 29, and a first exhaust port 61 arranged in a first differential evacuation chamber 910 between the first and second partition walls 91, 92. The first partition wall 91 includes a first opening 911 through which the reflection light 252 passes and a first partition plate 912 surrounding the first opening 911. The second partition wall 92 includes a second opening 921 smaller than the first opening 911 and a second partition plate 922 surrounding the second opening 921, and is arranged such that the reflection light 252 having passed through the first opening 911 passes through the second opening 921. An exhaust pump 31 is connected to the first exhaust port 61.

Further, the EUV light generation apparatus 1 includes a target sensor (not shown), a laser light transmission device (not shown), a processor (not shown), and the like. The target sensor detects at least one of the presence, trajectory, position, and velocity of the target 27. The target sensor may have an imaging function. The laser light transmission device is arranged between the laser device 3 and the chamber 2 and includes optical elements for defining a transmission state of the pulse laser light 33, and an actuator for adjusting the position, posture, and the like of the optical elements. The processor controls the entire EUV light generation system 11. The processor processes the detection result of the target sensor, and controls timing at which the target 27 is output, an output direction of the target 27, and the like based on the detection result of the target sensor. Further, the processor controls oscillation timing of the laser device 3, a travel direction of the pulse laser light 33, the concentration position of the pulse laser light 33, and the like.

### 1.2 Operation

The pulse laser light 33 output from the laser device 3 enters the chamber 2 through the window 21. The pulse laser light 33 passes through the second through hole 372 and is guided to the plasma generation region 25.

The target 27 output from the target supply unit 26 passes through the third through hole 373 and reaches the plasma generation region 25. The target 27 is irradiated with the pulse laser light 33. Among the plurality of targets 27, the targets 27 without being irradiated with the pulse laser light 33 and without being turned into plasma pass through the plasma generation region 25, further pass through the fourth through hole 374, and reach the target collection unit 28.

The target 27 irradiated with the pulse laser light 33 is turned into plasma, and radiation light 251 is radiated from the plasma. The radiation light 251 passes through the first through hole 371 and is incident on the EUV light concentrating mirror 23. EUV light contained in the radiation light 251 is reflected by the EUV light concentrating mirror 23 with higher reflectance than light in other wavelength ranges. Reflection light 252 including the EUV light reflected by the EUV light concentrating mirror 23 is concentrated at the intermediate focal point 292 and output to the EUV light utilization apparatus 6. Here, one target 27 may be irradiated with a plurality of pulses included in the pulse laser light 33. The plurality of pulses includes, for example, a prepulse and a main pulse.

The exhaust device 30 exhausts the gas in the third space 20c to the outside of the first inner wall 37 and the outside of the chamber 2 via the gate valve 39. As a result, the pressure in the third space 20c is maintained lower than the pressure in the first space 20a and the pressure in the second space 20b. Consequently, the gas flows from the second space 20b toward the third space 20c through the first through hole 371, and the gas flows from the first space 20a toward the third space 20c through the second to fourth through holes 372 to 374. Therefore, debris of the target substance generated at the vicinity of the plasma generation region 25 is suppressed from moving from the third space 20c to the first and second spaces 20a, 20b, and debris of the target substance is suppressed from being deposited on optical components such as the EUV light concentrating mirror 23 and the window 21.

The pressure in the second space 20b of the chamber 2 is, for example, around 100 Pa, and the pressure in the chamber of the EUV light utilization apparatus 6 is 10 Pa or less, for example, around 0.01 Pa. The differential evacuation device 90 exhausts the gas in the first differential evacuation chamber 910 through the first exhaust port 61, thereby suppressing the gas in the chamber 2 from flowing into the chamber of the EUV light utilization apparatus 6.

### 2. Problem of Comparative Example

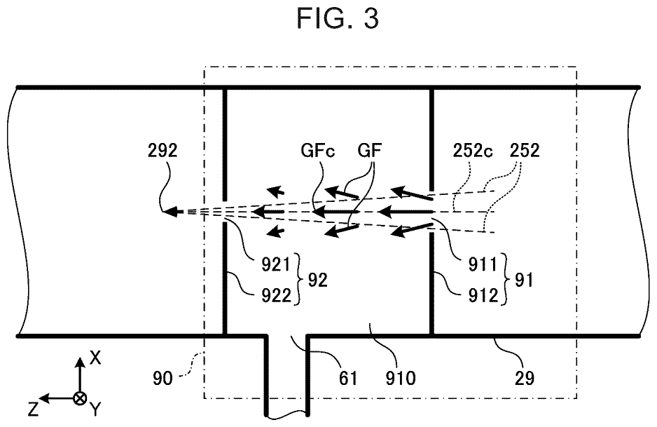

FIG. 3 shows the configuration of the differential evacuation device 90 shown in FIG. 1. When the gas in the first differential evacuation chamber 910 is exhausted and the pressure difference with respect to the chamber 2 increases, gas flow GF of the gas flowing into the first differential evacuation chamber 910 from the first opening 911 may be formed in a high-speed jet-like manner. The gas flow GF gradually weakens as approaching the second partition wall 92 from the first opening 911. However, when a center axis GFc of the gas flow GF is substantially coaxial with the optical path axis 252c of the reflection light 252 including the EUV light, pressure distribution at the second partition wall 92 on the first differential evacuation chamber 910 side may have a peak near the second opening 921. In this case, a gas inflow amount from the first differential evacuation chamber 910 into the EUV light utilization apparatus 6 through the second opening 921 increases.

When the gas inflow amount into the EUV light utilization apparatus 6 is large, the gas pressure in the EUV light utilization apparatus 6 increases, and the loss of the EUV light due to absorption of the EUV light by the gas in the EUV light utilization apparatus 6 increases. The embodiments described below relate to reducing the gas inflow amount from the first differential evacuation chamber 910 into the EUV light utilization apparatus 6.

### 3. Differential Evacuation Device 90a in which First Partition Wall 91a is Obliquely Arranged

### 3.1 Configuration

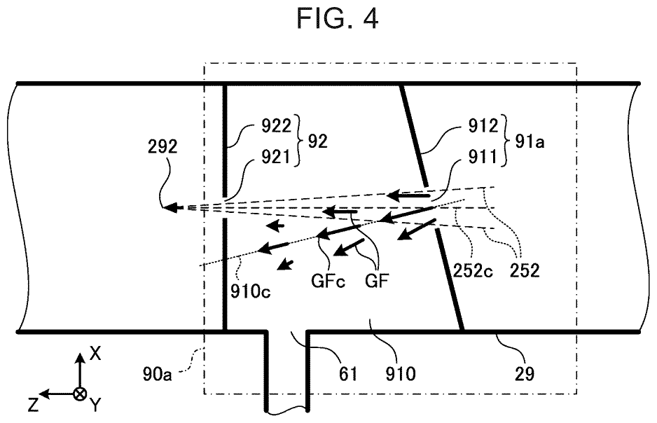

FIG. 4 shows the configuration of a differential evacuation device 90a according to a first embodiment. In the first embodiment, a first partition wall 91a is arranged non-perpendicularly with respect to the optical path axis 252c of the reflection light 252 including the EUV light. Non-perpendicular means that the angle is inclined by 3° or more with respect to 90°. The center axis GFc of the gas flow GF flowing from the first opening 911 into the first differential evacuation chamber 910 is substantially coaxial with a perpendicular axis 910c perpendicular to the first partition wall 91a and passing through the center of the first opening 911, and is substantially parallel to the XZ plane. Consequently, the center axis GFc of the gas flow GF intersects the second partition plate 922 instead of the second opening 921. As a result, the center axis GFc of the gas flow GF does not directly hit the second opening 921, and the peak of the pressure distribution at the second partition wall 92 on the first differential evacuation chamber 910 side shifts from the second opening 921, so that the gas inflow amount into the EUV light utilization apparatus 6 is reduced.

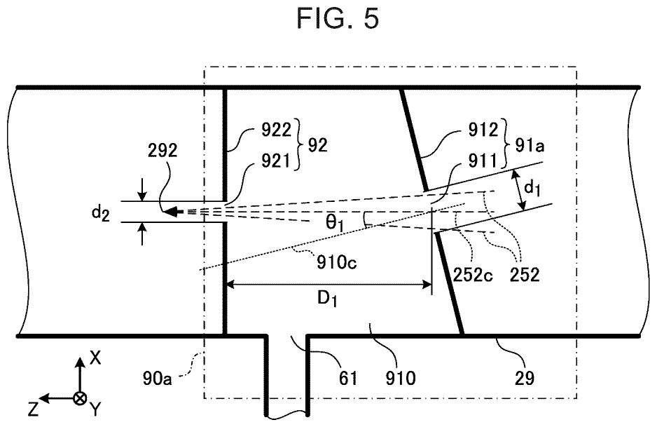

FIG. 5 shows the dimensions of the respective parts of the differential evacuation device 90a shown in FIG. 4. The distance between the center of the first opening 911 and the center of the second opening 921 is defined as D₁. The diameter of the second opening 921 is defined as d₂. Since the center axis GFc of the gas flow GF intersects the second partition plate 922, it is desirable that an angle θ1 between the optical path axis 252c of the reflection light 252 and the perpendicular axis 910c satisfies the following expression.

$$tan {θ}_{1} > {d}_{2} / 2 {D}_{1}$$

Further, assuming that the diameter of the first opening 911 is d₁ and the jet-like gas flow GF has a flow path cross section having a diameter of about d₁, it is desirable that the angle θ₁ satisfies the following expression to prevent the gas flow GF from hitting the second opening 921.

$$tan {θ}_{1} > ( {d}_{1} + {d}_{2} ) / 2 {D}_{1}$$

### 3.2 Pressure Distribution at Second Partition Plate 922 on First Differential Evacuation Chamber 910 Side

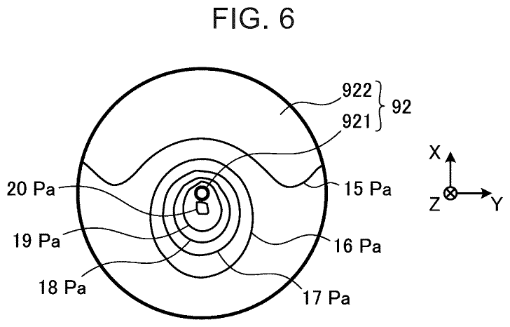

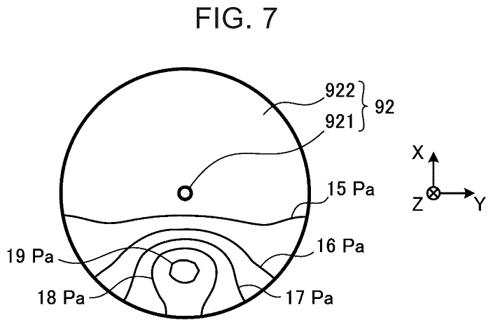

FIGS. 6 and 7 show a simulation result of the pressure distribution at the second partition plate 922 on the first differential evacuation chamber 910 side. The calculation conditions are as follows.
Gas pressure in second space 20b of chamber 2: 100 Pa
Gas pressure in chamber of EUV light utilization apparatus 6: 0.01 Pa
Gas pressure at first exhaust port 61: 0.1 Pa
Gas inflow amount from first opening 911: 26 nlm
Diameter d₁ of first opening 911: 20 mm
Diameter d₂ of second opening 921: 10 mm
Thickness of each of first and second partition walls 91a, 92: 5 mm
Distance D₁ between center of first opening 911 and center of second opening 921: 200 mm

Here, “nlm” represents the volume of the gas flowing per minute converted to that at 0° C. and 1 atm.

FIG. 6 shows the pressure distribution when the angle θ₁ is 0°, that is, in the case of the comparative example described above. Here, the minimum value of the pressure is about 15 Pa and the maximum value thereof is about 20 Pa. The second opening 921 is surrounded by a portion where the pressure is 19 Pa or higher, and there is a possibility that a large volume of the gas flows from the second opening 921 due to the pressure difference with respect to the EUV light utilization apparatus 6. The gas inflow amount from the second opening 921 into the EUV light utilization apparatus 6 was calculated to be 0.186 nlm.

FIG. 7 shows the pressure distribution when the angle θ₁ is 10° in the first embodiment. Here, the minimum value of the pressure is about 14 Pa and the maximum value thereof is about 19 Pa. The pressure around the second opening 921 is about 15 Pa, and has a smaller pressure difference with respect to the EUV light utilization apparatus 6 than the pressure around the second opening 921 in the comparative example. The gas inflow amount from the second opening 921 into the EUV light utilization apparatus 6 was calculated to be 0.132 nlm, which was reduced by 30% with respect to the inflow amount in the comparative example.

As shown in FIG. 7, it is desirable that the second opening 921 is surrounded by a portion outside a first high pressure region having the highest pressure in the pressure distribution at the second partition plate 922 on the first differential evacuation chamber 910 side. The first high pressure region having the highest pressure refers to a region having a pressure of 90% or more with respect to the peak value of the pressure. For example, when the peak value of the pressure is 20 Pa, it is desirable that the second opening 921 is surrounded by a portion outside the region having the pressure equal to or higher than 18 Pa.

Further, it is desirable that the second opening 921 is surrounded by a portion on the lower pressure side than the isobaric line of the median value in the pressure distribution. For example, when the median value in the pressure distribution is 16.5 Pa, it is desirable that the second opening 921 is surrounded by a portion having the pressure less than 16.5 Pa.

Further, it is desirable that the second opening 921 is located outside the longest isobaric line among the closed isobaric lines surrounding the first high pressure region in the pressure distribution. The closed isobaric line refers to an isobaric line which makes a circuit in the plane of the second partition plate 922, and does not refer to an isobaric line that reaches the outer edge of the second partition plate 922. In the pressure distribution shown in FIG. 7, the longest isobaric line among the closed isobaric lines is the isobaric line of 19 Pa, and it is desirable that the second opening 921 is located outside the isobaric line of 19 Pa. In the pressure distribution shown in FIG. 6, the longest isobaric line among the closed isobaric lines is the isobaric line of 16 Pa, and the second opening 921 is located inside the isobaric line of 16 Pa. However, when the direction of the gas flow GF changes and the position of the isobaric line of 16 Pa is shifted so that the second opening 921 is located outside the isobaric line of 16 Pa, this becomes a desirable example.

### 3.3 Position of First Exhaust Port 61

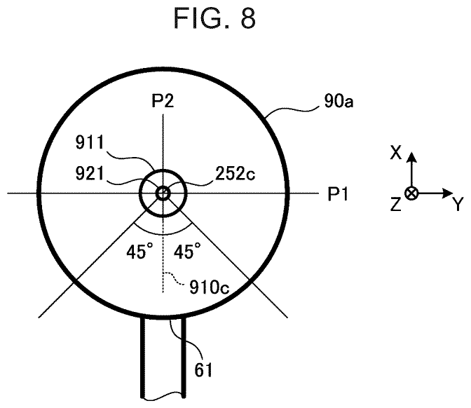

FIG. 8 shows the position of the first exhaust port 61 in the differential evacuation device 90a shown in FIG. 4. FIG. 8 is a view of the differential evacuation device 90a viewed in the Z direction. A plane including both the optical path axis 252c of the reflection light 252 passing through the centers of the first and second openings 911, 921 in the Z direction and the perpendicular axis 910c perpendicular to the first partition wall 91a and passing through the center of the first opening 911 is defined as a second plane P2. The perpendicular axis 910c approximately coincides with the center axis GFc of the gas flow GF. A plane including the optical path axis 252c and perpendicular to the second plane P2 is defined as a first plane P1.

The first exhaust port 61 is located in a space on the side, with respect to the first plane P1, where the perpendicular axis 910c and the second partition wall 92 intersect each other, that is, on the downstream side of the gas flow GF. More preferably, the first exhaust port 61 is located in a range within ±45° around the optical path axis 252c from the second plane P2 on the side, with respect to the first plane P1, where the perpendicular axis 910c and the second partition wall 92 intersect each other, that is, on the downstream side of the gas flow GF. When the gas in the vicinity of the first exhaust port 61 is sucked by the exhaust pump 31, there is a possibility that the gas flow GF is bent toward the first exhaust port 61. The possibility of the gas flow GF hitting the second opening 921 is further reduced by matching the direction in which the gas flow GF is bent by the exhaust pump 31 with the direction in which the gas flow GF is inclined by the inclination of the first partition wall 91a.

Referring back to FIG. 4, it is desirable that the distance between the first partition wall 91a and the first exhaust port 61 is larger than the distance between the second partition wall 92 and the first exhaust port 61. By arranging the first exhaust port 61 such that the distance from the second partition wall 92 is smaller than the distance from the first partition wall 91a, the gas reaching the vicinity of the second partition wall 92 can be efficiently exhausted from the first exhaust port 61.

### 3.4 Effect

(1) According to the first embodiment, the differential evacuation device 90a includes the connection pipe 29, the first partition wall 91a, the second partition wall 92, and the first exhaust port 61. The connection pipe 29 connects the chamber 2 which outputs the EUV light and the chamber of the EUV light utilization apparatus 6 to which the EUV light is input. Here, the chamber of the EUV light utilization apparatus 6 has a pressure lower than that of the chamber 2. The first partition wall 91a includes the first opening 911 and the first partition plate 912 surrounding the first opening 911, and is arranged in the connection pipe 29 such that the EUV light passes through the first opening 911. The second partition wall 92 includes the second opening 921 smaller than the first opening 911 and the second partition plate 922 surrounding the second opening 921, and is arranged such that the EUV light having passed through the first opening 911 passes through the second opening 921. The first exhaust port 61 exhausts the gas in the first differential evacuation chamber 910 between the first partition wall 91a and the second partition wall 92. The first partition wall 91a is arranged such that the second opening 921 is surrounded by the portion outside the first high pressure region where the pressure is highest in the pressure distribution at the second partition plate 922 on the first differential evacuation chamber 910 side.

Accordingly, since the second opening 921 is surrounded by the portion outside the first high pressure region, the gas flowing into the chamber of the EUV light utilization apparatus 6 is suppressed, and the loss due to absorption of the EUV light in the EUV light utilization apparatus 6 is suppressed.

(2) According to the first embodiment, the second opening 921 is surrounded by the portion on the lower pressure side than the isobaric line of the median value in the pressure distribution at the second partition plate 922 on the first differential evacuation chamber 910 side.

Accordingly, the pressure around the second opening 921 is lower than the median value, and the gas flowing into the chamber of the EUV light utilization apparatus 6 is suppressed.

(3) According to the first embodiment, the second opening 921 is located outside the longest isobaric line among the closed isobaric lines in the pressure distribution at the second partition plate 922 on the first differential evacuation chamber 910 side.

Accordingly, since the second opening 921 is located outside the longest isobaric line among the closed isobaric lines, the pressure around the second opening 921 is less likely to be affected by the jet-like gas flow GF, and the gas flowing into the chamber of the EUV light utilization apparatus 6 is suppressed.

(4) According to the first embodiment, the center axis GFc of the gas flow GF flowing from the first opening 911 into the first differential evacuation chamber 910 intersects the second partition plate 922.

Accordingly, the center of the gas flow GF is prevented from hitting the second opening 921, and the gas flowing into the chamber of the EUV light utilization apparatus 6 is suppressed.

(5) According to the first embodiment, the first exhaust port 61 is located in the space on the downstream side of the gas flow GF with respect to the first plane P1 which includes the optical path axis 252c of the EUV light passing through the first opening 911 and is perpendicular to the second plane P2 including the optical path axis 252c and the center axis GFc of the gas flow GF flowing from the first opening 911 into the first differential evacuation chamber 910.

Accordingly, by matching the inclination direction of the gas flow GF with the direction in which the gas flow GF is bent by the negative pressure caused by the exhaust through the first exhaust port 61, the possibility that the pressure around the second opening 921 is increased due to the effect of the gas flow GF is reduced.

(6) According to the first embodiment, the distance between the first partition wall 91a and the first exhaust port 61 is larger than the distance between the second partition wall 92 and the first exhaust port 61.

Accordingly, the gas reaching the vicinity of the second partition wall 92 can be efficiently exhausted from the first exhaust port 61.

(7) According to the first embodiment, the optical path axis 252c of the EUV light passing through the first opening 911 is non-perpendicular to the first partition wall 91a.

Accordingly, by inclining the first partition wall 91a, the gas flow GF can be inclined with respect to the optical path axis 252c, and the gas flowing into the chamber of the EUV light utilization apparatus 6 is suppressed.

(8) According to the first embodiment, assuming that the distance between the center of the first opening 911 and the center of the second opening 921 is D₁ and the diameter of the second opening 921 is d₂, the angle θ₁ between the optical path axis 252c and the perpendicular axis 910c perpendicular to the first partition wall 91a satisfies the following expression.

tanθ₁>d₂/2D₁

Accordingly, the center axis GFc of the gas flow GF can be inclined to be shifted from the second opening 921.

(9) According to the first embodiment, assuming that the distance between the center of the first opening 911 and the center of the second opening 921 is D₁, the diameter of the first opening 911 is d₁, and the diameter of the second opening 921 is d₂, the angle θ₁ between the optical path axis 252c and the perpendicular axis 910c perpendicular to the first partition wall 91a satisfies the following expression.

tanθ₁>(d₁+d₂)/2D₁

Accordingly, the entire width of the flow path of the gas flow GF can be inclined to be shifted from the second opening 921.

(10) According to the first embodiment, the first exhaust port 61 is located in the space on the side where the perpendicular axis 910c and the second partition wall 92 intersect each other with respect to the first plane P1 including the optical path axis 252c and perpendicular to the second plane P2 including the optical path axis 252c and the perpendicular axis 910c which is an axis perpendicular to the first partition wall 91a and passing through the center of the first opening 911.

Accordingly, by matching the inclination direction of the perpendicular axis 910c perpendicular to the first partition wall 91a with the direction in which the gas flow GF is bent by the negative pressure caused by the exhaust through the first exhaust port 61, the pressure around the second opening 921 can be reduced.

In other respects, the first embodiment is similar to the comparative example.

### 4. Differential Evacuation Devices 90b, 90c in which First Opening 911 is Obliquely Formed

### 4.1 Configuration

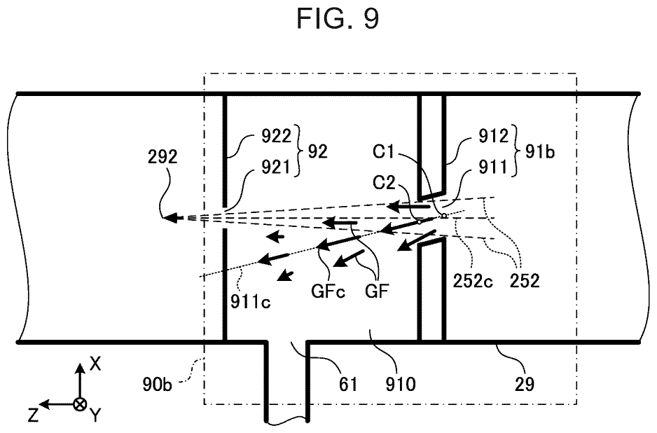

FIG. 9 shows the configuration of a differential evacuation device 90b according to a second embodiment. The first opening 911 has first and second positions differing in the thickness direction of the first partition wall 91b. The center of the first opening 911 at the first position is defined as C1 and the center of the first opening 911 at the second position is defined as C2. An axis passing through the centers C1, C2 is defined as an opening center axis 911c. In the second embodiment, the direction of the opening center axis 911c is different from the direction of the optical path axis 252c of the reflection light 252. Being different in direction means being inclined by 3° or more. The center axis GFc of the gas flow GF flowing from the first opening 911 into the first differential evacuation chamber 910 is substantially coaxial with the opening center axis 911c and substantially parallel to the XZ plane. Consequently, the center axis GFc of the gas flow GF intersects the second partition plate 922 instead of the second opening 921.

The thickness of the first partition plate 912 may be larger than the thickness of the second partition plate 922. The thickness of the first partition plate 912 is preferably 5 mm or more. The thickness of the first partition plate 912 may be, for example, 5 mm or 10 mm.

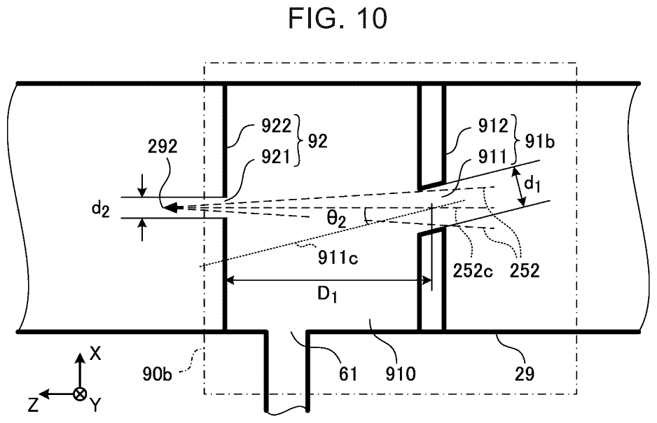

FIG. 10 shows the dimensions of the respective parts of the differential evacuation device 90b shown in FIG. 9. The center of the first opening 911 in defining the distance D₁ between the center of the first opening 911 and the center of the second opening 921 refers to the center of the first opening 911 at the center position in the thickness direction of the first partition wall 91b. It is desirable that an angle θ2 between the optical path axis 252c of the reflection light 252 and the opening center axis 911c satisfies the following expression.

$$tan {θ}_{2} > {d}_{2} / 2 {D}_{1}$$

Further, it is desirable that the angle θ₂ satisfies the following expression.

$$tan {θ}_{2} > ( {d}_{1} + {d}_{2} ) / 2 {D}_{1}$$

Assuming that the angle θ₂ is 10°, the gas inflow amount from the second opening 921 into the EUV light utilization apparatus 6 in the second embodiment was calculated in a similar manner as in the first embodiment. Consequently, the gas inflow amount when the thickness of the first partition wall 91b is 10 mm was 0.116 nlm, and was reduced by 38% with respect to the inflow amount in the comparative example. When the thickness of the first partition wall 91b is 5 mm, the gas inflow amount was 0.146 nlm, and was reduced by 22% with respect to the inflow amount in the comparative example.

### 4.2 Position of First Exhaust Port 61

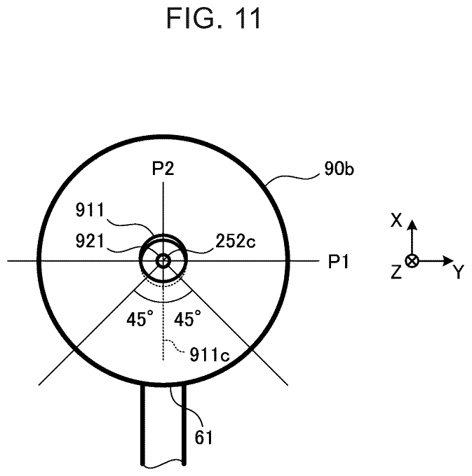

FIG. 11 shows the position of the first exhaust port 61 in the differential evacuation device 90b shown in FIG. 9. FIG. 11 is a view of the differential evacuation device 90b viewed in the Z direction. The plane including both the optical path axis 252c and the opening center axis 911c is defined as the second plane P2. The plane including the optical path axis 252c and perpendicular to the second plane P2 is defined as the first plane P1.

The first exhaust port 61 is located in a space on the side, with respect to the first plane P1, where the opening center axis 911c and the second partition wall 92 intersect each other, that is, on the downstream side of the gas flow GF. More preferably, the first exhaust port 61 is located in a range within ±45° around the optical path axis 252c from the second plane P2 on the side, with respect to the first plane P1, where the opening center axis 911c and the second partition wall 92 intersect each other, that is, on the downstream side of the gas flow GF.

### 4.3 Modification

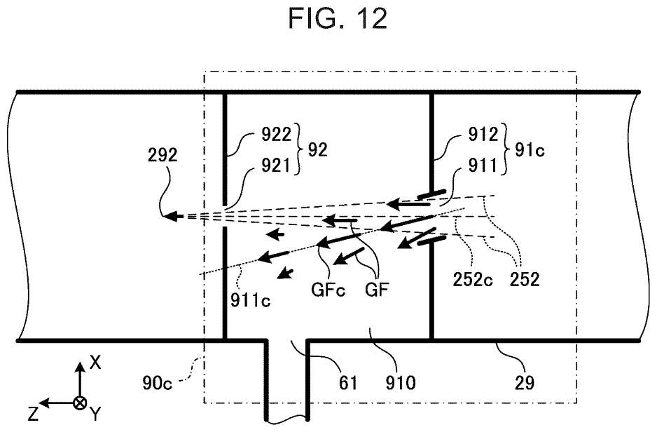

FIG. 12 shows the configuration of a differential evacuation device 90c according to a modification of the second embodiment. While the thickness of the entire first partition plate 912 is large and uniform in FIG. 9, the thickness of only a part of the first partition plate 912 is large in FIG. 12. The thickness of the first partition plate 912 may be increased at least in a region surrounding the first opening 911,

### 4.4 Effect

According to the second embodiment, the direction of the optical path axis 252c of the EUV light passing through the first opening 911 differs from the direction of the opening center axis 911c, which is the axis passing through the centers C1, C2 of the first opening 911 at the respective positions in the thickness direction of the first partition wall 91b.

Accordingly, by forming the first opening 911 obliquely, the gas flow GF can be inclined with respect to the optical path axis 252c, and the gas flowing into the chamber of the EUV light utilization apparatus 6 is suppressed.

(12) According to the second embodiment, assuming that the distance between the center of the first opening 911 and the center of the second opening 921 is D₁ and the diameter of the second opening 921 is d₂, the angle θ₂ between the optical path axis 252c and the opening center axis 911c satisfies the following expression.

$$tan {θ}_{2} > {d}_{2} / 2 {D}_{1}$$

Accordingly, the center axis GFc of the gas flow GF can be inclined to be shifted from the second opening 921.

(13) According to the second embodiment, assuming that the distance between the center of the first opening 911 and the center of the second opening 921 is D₁, the diameter of the first opening 911 is d₁, and the diameter of the second opening 921 is d₂, the angle θ₂ between the optical path axis 252c and the opening center axis 911c satisfies the following expression.

$$tan {θ}_{2} > ( {d}_{1} + {d}_{2} ) / 2 {D}_{1}$$

Accordingly, the entire width of the flow path of the gas flow GF can be inclined to be shifted from the second opening 921.

(14) According to the second embodiment, the thickness of the first partition plate 912 around the first opening 911 is 5 mm or more.

Accordingly, since the length of the first opening 911 in the thickness direction of the first partition plate 912 is 5 mm or more, the gas flow GF can be inclined by the first opening 911 formed obliquely.

(15) According to the second embodiment, the first exhaust port 61 is located in the space on the side where the opening center axis 911c and the second partition wall 92 intersect each other with respect to the first plane P1 including the optical path axis 252c and perpendicular to the second plane P2 including the opening center axis 911c and the optical path axis 252c.

Accordingly, by matching the inclination direction of the opening center axis 911c of the first opening 911 with the direction in which the gas flow GF is bent by the negative pressure caused by the exhaust through the first exhaust port 61, the pressure around the second opening 921 may be reduced.

In other respects, the second embodiment is similar to the first embodiment.

### 5. Differential Evacuation Devices 90d, 90e in which Thickness of First Partition Plate 912 is Partially Different

### 5.1 Configuration

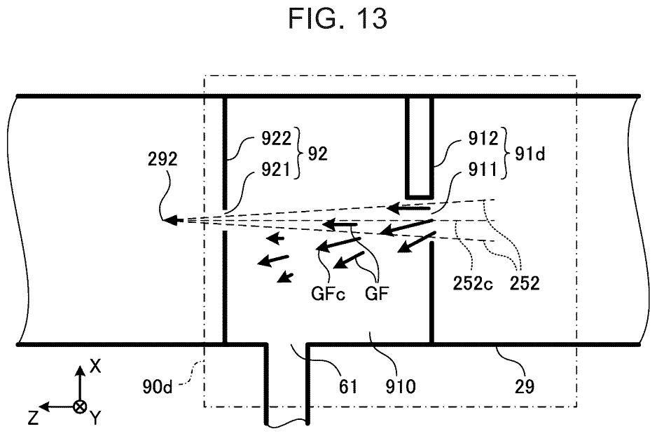

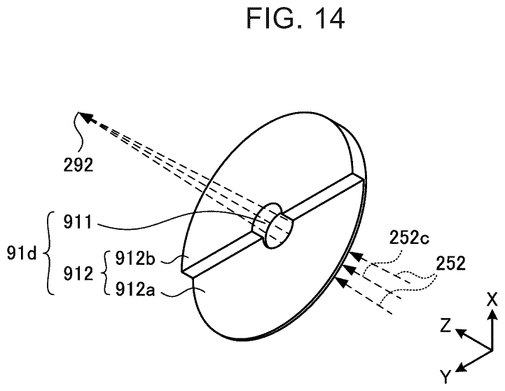

FIG. 13 shows the configuration of a differential evacuation device 90d according to a third embodiment. FIG. 14 is a perspective view of a first partition wall 91d shown in FIG. 13. In the third embodiment, the first partition plate 912 configuring the first partition wall 91d includes a first portion 912a having a first thickness and being in contact with the space in the first opening 911, and a second portion 912b having a second thickness larger than the first thickness and being in contact with the above space. For example, one of the two halves of the first partition plate 912, which is obtained by dividing the first partition plate 912 at the diameter in parallel to the Y direction, is the first portion 912a, and the other thereof is the second portion 912b. The step between the first portion 912a and the second portion 912b is located on the first differential evacuation chamber 910 side.

The gas flowing from the first opening 911 into the first differential evacuation chamber 910 is suppressed from flowing in the X direction where the second portion 912b is located, and easily flows in the −X direction where the first portion 912a is located. Consequently, the center axis GFc of the gas flow GF substantially parallel to the XZ plane is inclined with respect to the first partition wall 91d and intersects the second partition plate 922 instead of the second opening 921. The difference between the first thickness and the second thickness is 5 mm or larger and 30 mm or smaller.

The gas inflow amount from the second opening 921 into the EUV light utilization apparatus 6 in the third embodiment was calculated in a similar manner as in the first embodiment. Consequently, the gas inflow amount when the first and second thicknesses are 5 mm and 35 mm, respectively, was 0.104 nlm, and was reduced by 44% with respect to the inflow amount in the comparative example. The gas inflow amount when the first and second thicknesses are 5 mm and 10 mm, respectively, was 0.115 nlm, and was reduced by 38% with respect to the inflow amount in the comparative example.

### 5.2 Modification

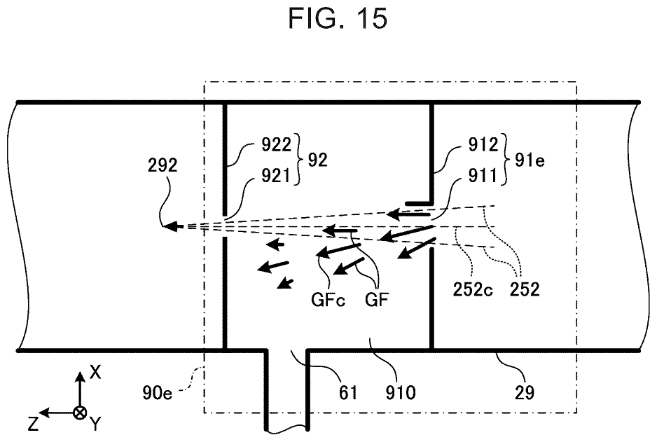

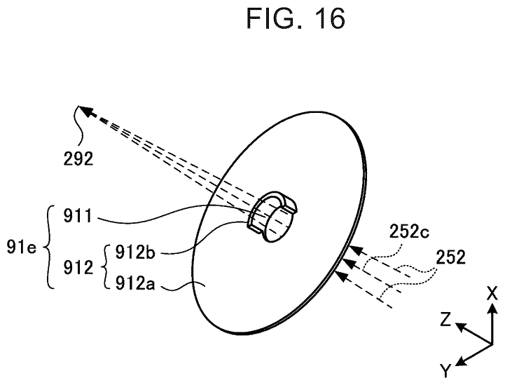

FIG. 15 shows the configuration of a differential evacuation device 90e according to a modification of the third embodiment. FIG. 16 is a perspective view of a first partition wall 91e shown in FIG. 15. Although FIGS. 13 and 14 show the case in which the entire semi-circular portion obtained by dividing the first partition plate 912 into halves at the diameter in parallel to the Y direction is used as the second portion 912b, the second portion 912b may have an eaves-like shape arranged only in the vicinity of the first opening 911 as shown in FIGS. 15 and 16.

### 5.3 Effect

(16) According to the third embodiment, the first partition plate 912 includes the first portion 912a having the first thickness and being in contact with the space in the first opening 911, and the second portion 912b having the second thickness larger than the first thickness and being in contact with the above space.

Accordingly, by making the thicknesses of the first portion 912a and the second portion 912b in contact with the first opening 911 different from each other, the gas flow GF can be inclined toward the first portion 912a having a smaller thickness, and the gas flowing into the chamber of the EUV light utilization apparatus 6 is suppressed.

(17) According to the third embodiment, the difference between the first thickness and the second thickness is 5 mm or larger and 30 mm or smaller.

Accordingly, by setting the difference between the first thickness and the second thickness to be 5 mm or larger, the gas flow GF can be inclined, and by setting the difference to be 30 mm or smaller, the space in the first differential evacuation chamber 910 can be sufficiently secured.

In other respects, the third embodiment is similar to the first and second embodiments.

### 6. Differential Evacuation Device 90f Including Plurality of Differential Evacuation Chambers 910, 920, 930

### 6.1 Configuration

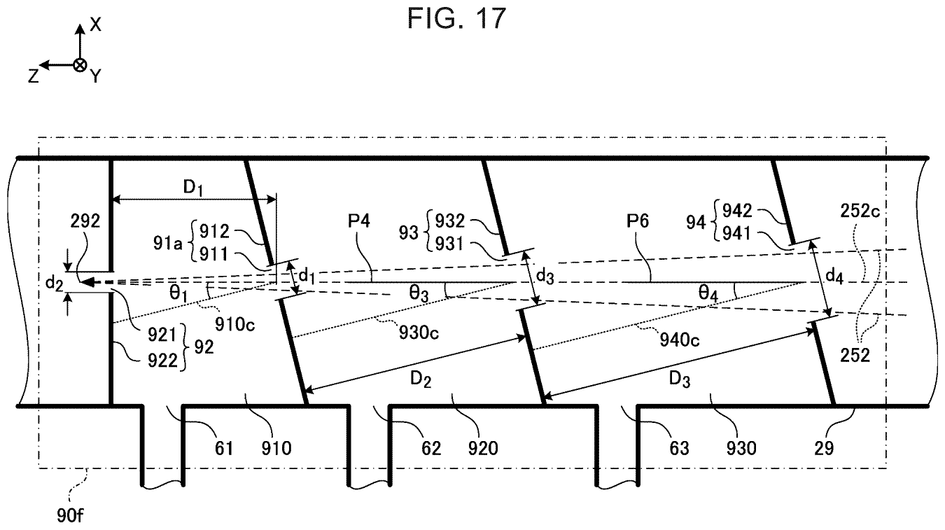

FIG. 17 shows the configuration of a differential evacuation device 90f according to a fourth embodiment. The differential evacuation device 90f includes a third partition wall 93 in addition to the first and second partition walls 91a, 92. The differential evacuation device 90f may further include a fourth partition wall 94.

The third and fourth partition walls 93, 94 are arranged in the connection pipe 29. The third partition wall 93 includes a third opening 931 larger than the first opening 911 and a third partition plate 932 surrounding the third opening 931. The fourth partition wall 94 includes a fourth opening 941 larger than the third opening 931 and a fourth partition plate 942 surrounding the fourth opening 941. The third and fourth partition walls 93, 94 are arranged such that the reflection light 252 including the EUV light having passed through the fourth opening 941 sequentially passes through the third opening 931 and the first opening 911.

A second exhaust port 62 is arranged at a second differential evacuation chamber 920 between the first and third partition walls 91a, 93, and a third exhaust port 63 is arranged at a third differential evacuation chamber 930 between the third and fourth partition walls 93, 94. An exhaust pump (not shown) is connected to each of the second and third exhaust ports 62, 63.

In FIG. 17, the gas flow GF flowing from the third opening 931 into the second differential evacuation chamber 920 and the center axis GFc thereof are omitted, and instead, a perpendicular axis 930c perpendicular to the third partition wall 93 and passing through the center of the third opening 931 is shown. Further, the gas flow GF flowing from the fourth opening 941 into the third differential evacuation chamber 930 and the center axis GFc thereof are omitted, and instead, a perpendicular axis 940c perpendicular to the fourth partition wall 94 and passing through the center of the fourth opening 941 is shown.

The third and fourth partition walls 93, 94 are arranged non-perpendicularly to the optical path axis 252c of the reflection light 252. The perpendicular axis 930c intersects the first partition plate 912 instead of the first opening 911. Accordingly, it is desirable that the first opening 911 is surrounded by a portion outside a second high pressure region where the pressure is highest in the pressure distribution at the first partition plate 912 on the second differential evacuation chamber 920 side. Similarly, the perpendicular axis 940c intersects the third partition plate 932 instead of the third opening 931. With the above configuration, the gas inflow amount into the EUV light utilization apparatus 6 is reduced.

It is assumed that the first partition wall 91a and the third partition wall 93 are arranged in parallel, and the distance between the first partition wall 91a and the third partition wall 93 is D₂. It is desirable that the angle θ₃ between the optical path axis 252c of the reflection light 252 and the perpendicular axis 930c perpendicular to the third partition wall 93 satisfies the following expression.

$$tan {θ}_{3} > {d}_{1} / 2 {D}_{2}$$

Further, assuming that the diameter of the third opening 931 is d₃ and the jet-like gas flow GF flowing into the second differential evacuation chamber 920 has a flow path cross section having a diameter of about d₃, it is desirable that the angle θ₃ satisfies the following expression.

$$tan {θ}_{3} > ( {d}_{1} + {d}_{3} ) / 2 {D}_{2}$$

It is assumed that the third partition wall 93 and the fourth partition wall 94 are arranged in parallel, and the distance between the third partition wall 93 and the fourth partition wall 94 is D₃. It is desirable that the angle θ₄ between the optical path axis 252c of the reflection light 252 and the perpendicular axis 940c perpendicular to the fourth partition wall 94 satisfies the following expression.

$$tan {θ}_{4} > {d}_{3} / 2 {D}_{3}$$

Further, assuming that the diameter of the fourth opening 941 is d₄ and the jet-like gas flow GF flowing into the third differential evacuation chamber 930 has a flow path cross section having a diameter of about d₄, it is desirable that the angle θ₄ satisfies the following expression.

$$tan {θ}_{4} > ( {d}_{3} + {d}_{4} ) / 2 {D}_{3}$$

Similarly to the first partition wall 91a of the first embodiment, the third and fourth partition walls 93, 94 are arranged obliquely, but the present disclosure is not limited thereto. Similarly to the first partition wall 91b of the second embodiment or the first partition wall 91c of the modification thereof, at least one of the third and fourth partition walls 93, 94 may have an opening formed obliquely. Similarly to the first partition wall 91d of the third embodiment or the first partition wall 91e of the modification thereof, at least one of the third and fourth partition walls 93, 94 may have a plurality of portions that are in contact with a space in the same opening and have different thicknesses.

### 6.2 Position of Second and Third Exhaust Ports 62, 63

A plane including both the optical path axis 252c of the reflection light 252 and the perpendicular axis 930c passing through the center of the third opening 931 and perpendicular to the third partition wall 93 is referred to as a third plane (not shown). A plane including the optical path axis 252c and perpendicular to the third plane is defined as a fourth plane P4.

The second exhaust port 62 is located in a space on the side, with respect to the fourth plane P4, where the perpendicular axis 930c and the first partition wall 91a intersect each other, that is, on the downstream side of the gas flow GF. More preferably, the second exhaust port 62 is located in a range within ±45° around the optical path axis 252c from the third plane on the side, with respect to the fourth plane P4, where the perpendicular axis 930c and the first partition wall 91a intersect each other, that is, on the downstream side of the gas flow GF.

It is desirable that the distance between the third partition wall 93 and the second exhaust port 62 is larger than the distance between the first partition wall 91a and the second exhaust port 62.

A plane including both the optical path axis 252c of the reflection light 252 and the perpendicular axis 940c passing through the center of the fourth opening 941 and perpendicular to the fourth partition wall 94 is referred to as a fifth plane (not shown). A plane including the optical path axis 252c and perpendicular to the fifth plane is defined as a sixth plane P6.

The third exhaust port 63 is located in a space on the side, with respect to the sixth plane P6, where the perpendicular axis 940c and the third partition wall 93 intersect each other, that is, on the downstream side of the gas flow GF. More preferably, the third exhaust port 63 is located in a range within ±45° around the optical path axis 252c from the fifth plane on the side, with respect to the sixth plane P6, where the perpendicular axis 940c and the third partition wall 93 intersect each other, that is, on the downstream side of the gas flow GF.

It is desirable that the distance between the fourth partition wall 94 and the third exhaust port 63 is larger than the distance between the third partition wall 93 and the third exhaust port 63.

### 6.3 Effect

(18) According to the fourth embodiment, the differential evacuation device 90f further includes the third partition wall 93 and the second exhaust port 62. The third partition wall 93 includes the third opening 931 larger than the first opening 911 and the third partition plate 932 surrounding the third opening 931, and is arranged such that the EUV light having passed through the third opening 931 passes through the first opening 911. The second exhaust port 62 exhausts the gas in the second differential evacuation chamber 920 between the third partition wall 93 and the first partition wall 91a. The third partition wall 93 is arranged such that the first opening 911 is surrounded by a portion outside the first high pressure region where the pressure is highest in the pressure distribution at the first partition plate 912 on the second differential evacuation chamber 920 side.

Accordingly, since the gas flowing into the subsequent stage can be suppressed in each of two or more stages of the differential evacuation chambers, the gas flowing into the chamber of the EUV light utilization apparatus 6 can be sufficiently suppressed.

In other respects, the fourth embodiment is similar to the first to third embodiments.

### 7. Others

### 7.1 Examples of EUV Light Utilization Apparatus 6

FIG. 18 schematically shows the configuration of the exposure apparatus 6a connected to the EUV light generation system 11. In FIG. 18, the exposure apparatus 6a as the EUV light utilization apparatus 6 (see FIG. 1) includes a mask irradiation unit 608 and a workpiece irradiation unit 609. The mask irradiation unit 608 illuminates, via a reflection optical system, a mask pattern of a mask table MT with the EUV light incident from the EUV light generation system 11. The workpiece irradiation unit 609 images the EUV light reflected by the mask table MT onto a workpiece (not shown) arranged on a workpiece table WT via a reflection optical system. The workpiece is a photosensitive substrate such as a semiconductor wafer on which photoresist is applied. The exposure apparatus 6a synchronously translates the mask table MT and the workpiece table WT to expose the workpiece to the EUV light reflecting the mask pattern. Through the exposure process as described above, a device pattern is transferred onto the semiconductor wafer, thereby an electronic device can be manufactured.

FIG. 19 schematically shows the configuration of the inspection apparatus 6b connected to the EUV light generation system 11. In FIG. 19, the inspection apparatus 6b as the EUV light utilization apparatus 6 (see FIG. 1) includes an illumination optical system 603 and a detection optical system 606. The illumination optical system 603 reflects the EUV light incident from the EUV light generation system 11 to illuminate a mask 605 placed on a mask stage 604. Here, the mask 605 conceptually includes a mask blanks before a pattern is formed. The detection optical system 606 reflects the EUV light from the illuminated mask 605 and forms an image on a light receiving surface of a detector 607. The detector 607 having received the EUV light obtains the image of the mask 605. The detector 607 is, for example, a time delay integration (TDI) camera. A defect of the mask 605 is inspected based on the image of the mask 605 acquired by the above-described process, and a mask suitable for manufacturing an electronic device is selected using the inspection result. Then, the electronic device can be manufactured by exposing and transferring the pattern formed on the selected mask onto the photosensitive substrate using the exposure apparatus 6a.

### 7.2 Supplement

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A differential evacuation device comprising:
a connection pipe which connects a first chamber which outputs extreme ultraviolet light and a second chamber to which the extreme ultraviolet light is input as having a pressure lower than the first chamber;
a first partition wall including a first opening and a first partition plate surrounding the first opening and being arranged such that the extreme ultraviolet light passes through the first opening;
a second partition wall including a second opening smaller than the first opening and a second partition plate surrounding the second opening and being arranged such that the extreme ultraviolet light having passed through the first opening passes through the second opening; and
a first exhaust port configured to exhaust a gas in a first differential evacuation chamber between the first partition wall and the second partition wall,
the first partition wall being arranged such that the second opening is surrounded by a portion outside a first high pressure region where a pressure is highest in pressure distribution at the second partition plate on the first differential evacuation chamber side.

2. The differential evacuation device according to claim 1,
wherein the second opening is surrounded by a portion on a lower pressure side than an isobaric line of a median value in the pressure distribution at the second partition plate on the first differential evacuation chamber side.

3. The differential evacuation device according to claim 1,
wherein the second opening is located outside a longest isobaric line among closed isobaric lines in the pressure distribution at the second partition plate on the first differential evacuation chamber side.

4. The differential evacuation device according to claim 1,
wherein a center axis of a gas flow flowing from the first opening into the first differential evacuation chamber intersects the second partition plate.

5. The differential evacuation device according to claim 1,
wherein the first exhaust port is located in a space on a downstream side of a gas flow flowing from the first opening into the first differential evacuation chamber with respect to a first plane which includes an optical path axis of the extreme ultraviolet light passing through the first opening and is perpendicular to a second plane including the optical path axis and a center axis of the gas flow.

6. The differential evacuation device according to claim 1,
wherein a distance between the first partition wall and the first exhaust port is larger than a distance between the second partition wall and the first exhaust port.

7. The differential evacuation device according to claim 1,
wherein an optical path axis of the extreme ultraviolet light passing through the first opening is non-perpendicular to the first partition wall.

8. The differential evacuation device according to claim 7,
wherein, assuming that a distance between a center of the first opening and a center of the second opening is D₁ and a diameter of the second opening is d₂, an angle θ1 between the optical path axis and a perpendicular axis perpendicular to the first partition wall satisfies an expression of taneθ₁>d₂/2D₁.

9. The differential evacuation device according to claim 7,
wherein, assuming that a distance between a center of the first opening and a center of the second opening is D₁, a diameter of the first opening is d₁, and a diameter of the second opening is d₂, an angle θ₁ between the optical path axis and a perpendicular axis perpendicular to the first partition wall satisfies an expression of taneθ₁>(d₁+d₂)/2D₁.

10. The differential evacuation device according to claim 7,
wherein the first exhaust port is located in a space on a side where a perpendicular axis, which is an axis perpendicular to the first partition wall and passing through a center of the first opening, and the second partition wall intersect each other with respect to a first plane including the optical path axis and being perpendicular to a second plane including the optical path axis and the perpendicular axis.

11. The differential evacuation device according to claim 1,
wherein a direction of an optical path axis of the extreme ultraviolet light passing through the first opening differs from a direction of an opening center axis, which is an axis passing through centers of the first opening at respective positions in a thickness direction of the first partition wall.

12. The differential evacuation device according to claim 11,
wherein, assuming that a distance between a center of the first opening and a center of the second opening is D₁ and a diameter of the second opening is d₂, an angle θ₂ between the optical path axis and the opening center axis satisfies an expression of tanθ₂>d₂/2D₁.

13. The differential evacuation device according to claim 11,
wherein, assuming that a distance between a center of the first opening and a center of the second opening is D₁, a diameter of the first opening is d₁, and a diameter of the second opening is d₂, an angle θ₂ between the optical path axis and the opening center axis satisfies an expression of tanθ₂>(d₁+d₂)/2D₁.

14. The differential evacuation device according to claim 11,
wherein a thickness of the first partition plate around the first opening is 5 mm or more.

15. The differential evacuation device according to claim 11,
wherein the first exhaust port is located in a space on a side where the opening center axis and the second partition wall intersect each other with respect to a first plane including the optical path axis and being perpendicular to a second plane including the opening center axis and the optical path axis.

16. The differential evacuation device according to claim 1,
wherein the first partition plate includes a first portion having a first thickness and being in contact with a space in the first opening, and a second portion having a second thickness larger than the first thickness and being in contact with the space.

17. The differential evacuation device according to claim 16,
wherein a difference between the first thickness and the second thickness is 5 mm or larger and 30 mm or smaller.

18. The differential evacuation device according to claim 1, further comprising:
a third partition wall including a third opening larger than the first opening and a third partition plate surrounding the third opening and being arranged such that the extreme ultraviolet light having passed through the third opening passes through the first opening; and
a second exhaust port configured to exhaust a gas in a second differential evacuation chamber between the third partition wall and the first partition wall,
wherein the third partition wall is arranged such that the first opening is surrounded by a portion outside a second high pressure region where a pressure is highest in pressure distribution at the first partition plate on the second differential evacuation chamber side.

19. An electronic device manufacturing method, comprising:
generating extreme ultraviolet light using an extreme ultraviolet light generation system;
outputting the extreme ultraviolet light to an exposure apparatus including a second chamber; and
exposing a photosensitive substrate to the extreme ultraviolet light in the exposure apparatus to manufacture an electronic device,
the extreme ultraviolet light generation system including a first chamber and a differential evacuation device,
the differential evacuation device including:
a connection pipe which connects the first chamber which outputs the extreme ultraviolet light and the second chamber to which the extreme ultraviolet light is input as having a pressure lower than the first chamber;
a first partition wall including a first opening and a first partition plate surrounding the first opening and being arranged such that the extreme ultraviolet light passes through the first opening;
a second partition wall including a second opening smaller than the first opening and a second partition plate surrounding the second opening and being arranged such that the extreme ultraviolet light having passed through the first opening passes through the second opening; and
a first exhaust port configured to exhaust a gas in a first differential evacuation chamber between the first partition wall and the second partition wall,
the first partition wall being arranged such that the second opening is surrounded by a portion outside a first high pressure region where a pressure is highest in pressure distribution at the second partition plate on the first differential evacuation chamber side.

20. An electronic device manufacturing method, comprising:
inspecting a defect of a mask by irradiating the mask with extreme ultraviolet light generated by an extreme ultraviolet light generation system;
selecting a mask using a result of the inspection; and
exposing and transferring a pattern formed on the selected mask onto a photosensitive substrate,
the extreme ultraviolet light generation system including a first chamber and a differential evacuation device,
the differential evacuation device including:
a connection pipe which connects the first chamber which outputs the extreme ultraviolet light and a second chamber to which the extreme ultraviolet light is input as having a pressure lower than the first chamber;
a first partition wall including a first opening and a first partition plate surrounding the first opening and being arranged such that the extreme ultraviolet light passes through the first opening;
a second partition wall including a second opening smaller than the first opening and a second partition plate surrounding the second opening and being arranged such that the extreme ultraviolet light having passed through the first opening passes through the second opening; and
a first exhaust port configured to exhaust a gas in a first differential evacuation chamber between the first partition wall and the second partition wall,
the first partition wall being arranged such that the second opening is surrounded by a portion outside a first high pressure region where a pressure is highest in pressure distribution at the second partition plate on the first differential evacuation chamber side.
